(19) United States
(12) Patent Application Publication
(10) Pub. No.: US 2026/0299067 A1
(43) Pub. Date: Oct. 1, 2026

(54) LOCAL COIL DEVICE, MAGNETIC RESONANCE DEVICE, AND METHOD FOR DETERMINING AN INCLINATION

(71) Applicant: Siemens Healthineers AG, Forchheim (DE)

(72) Inventors: Johann Sukkau, Herzogenaurach (DE); Matthias Malzacher, Nürnberg (DE)

(21) Appl. No.: 19/629,699

(22) Filed: Mar. 26, 2026

(30) Foreign Application Priority Data
Mar. 26, 2025 (DE) 10 2025 111 743.8

(51) Int. Cl. G01R 33/48; G01C 9/00; G01R 33/28; G01R 33/421

(52) U.S. Cl. CPC G01R 33/481; G01C 9/00; G01R 33/288; G01R 33/4215

(57) ABSTRACT

Device and method for optical, wireless data transmission between components of a magnetic resonance tomograph

The invention relates to a peripheral apparatus for a magnetic resonance tomograph with an optical transmitter for transmitting data over free space, as well as a magnetic resonance tomograph having an optical receiver with a light guide in a patient tunnel which is designed to couple optical signals from an environment, and a method for operation.

This application claims the benefit of German Patent Application No. DE 10 2025 111 743.8, filed on Mar. 26, 2025, which is hereby incorporated by reference in its entirety.

### BACKGROUND

The present embodiments relate to a local coil device for a magnetic resonance device, the magnetic resonance device, and a method for determining an inclination of a second portion of the local coil device that is tiltable relative to a first portion of the local coil device.

A local coil device is a radio frequency coil arrangement that may include one or more antenna elements or coil elements. These individual coil elements may be configured as loop antennas, butterfly coils, and/or saddle coils. In addition to the coil elements, the local coil device may include a preamplifier, additional electronics and cabling, a housing, and/or, in many cases, a cable with a connector through which the local coil device may be connected to the magnetic resonance device. If the local coil device is configured as a head coil device (often referred to as a “head coil” for short), the patient's head may be placed in the housing between a plurality of coil elements in order to perform a magnetic resonance measurement. If the local coil device is to be used for positioning patients with changes to the cervical spine such that the patient is unable to lay their head flat in the coil, the head coil device may be configured to be tiltable. By tilting the upper part of the head coil device, for example, patient comfort may be improved thanks to the various positions available, and patients with pathological changes to the cervical spine may have their head positioned in the head coil. The head coil may assume three different tilt positions, for example. In order for these three positions to be identified, the respective positions are detected with the aid of light barriers. However, a disadvantage of these light barriers is that they regularly become non-functional after a certain amount of time because the LEDs only have a limited service life. Further, in order to transfer the information relating to the respective tilt position of the head coil to the magnetic resonance device, a different coil code is used for every possible tilt position. It is therefore necessary to provide a different set of coil information (e.g., “coil files”) that, for example, describes the positions of the coil elements for every tilt position. If it is intended to realize the tilt positions continuously (e.g., in a range from 0-45°), the number of coil codes and thus sets of coil information would become very large. In this situation, it would therefore be necessary to limit the number of permitted tilt positions and pivot to a discrete approximation of 1° increments, for example. In the case of the above example, 45 sets of coil information would be necessary for this.

With respect to the geometrical position of the coil elements, the coil information is used, for example, to estimate the SAR of the patient (e.g., for an advance calculation). A precise estimation and knowledge of the arrangement of the coil elements with respect to the patient is particularly important with respect to local hotspots. It is also conceivable to take them into consideration in the reconstruction of magnetic resonance image data sets.

DE 10 2014 214 704 A1 describes a head coil for an imaging magnetic resonance system, the head coil having an upper part and a lower part, and the lower part having a lower part base and a movable lower part. The movable lower part may be brought into predefined positions by means of locking bolts.

Further, a method for transferring time-synchronized data from pointer-type measuring instruments in magnetic resonance tomography is known from the prior art. The transfer takes place optically or via ultrasound. In the case of an optical or infrared transfer, fiber optic cables are installed along the patient table and radiate the infrared light in all directions via a diode. The radiated light is then guided to an infrared receiver. In the case of a transfer via ultrasound, a plurality of ultrasonic transmitters and ultrasonic receivers are installed in the table, analogously to the optical transfer method.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, an improved basis, such as one that is easy to implement and keeps disruption of the magnetic resonance measurement to a minimum, for the use of local coil devices with tiltable portions in a magnetic resonance device is provided.

In one embodiment, a local coil device has an acceleration sensor on a second portion, the sensor data of which may be used to determine inclination information with respect to an inclination and/or a change in the inclination of the tiltable portion of the local coil device.

According to the present embodiments, the local coil device may be configured as a head coil device, as the tiltability is particularly useful, especially for patients with restricted mobility. To measure the inclination of the tiltable portion (e.g., with respect to the fixed portion), an acceleration sensor that, with the local coil device stationary, may at least measure the orientation of the tiltable second portion with respect to the vertical and thus also the change in this orientation is used. The underlying principle is that the local coil device may be installed with its fixed first portion such that a defined orientation with respect to the vertical is established for the latter. Further, the tilting occurs at least partially relative to the horizontal plane (e.g., about an at least essentially horizontal tilt axis). The sensor data may thus also be used to determine a tilt angle between the first portion and the second portion, from which, for example, based on a single piece of coil information, the geometry contained therein (e.g., the position of the coil elements) may be adapted accordingly, with further details of this being provided in the following. The acceleration sensor thus permits continuous adjustment and measurement thereof so that restriction to specific positions is no longer necessary. In this respect, the local coil device may have a detent that enables locking anywhere within a tilt range (e.g., from 0 to 45°).

For an acceleration sensor, the service life of the sensor system is longer than the previous prior art with light barriers, where the service life of the LEDs installed in the light barriers is a limiting factor.

The acceleration sensor may be provided in the form of a micro-electromechanical system (MEMS). The acceleration sensor is thus extremely compact and may be provided without complex redesigning of the second portion. In general terms, the acceleration sensor may be arranged on a circuit board installed in the second portion. Owing to the small dimensions of the sensor, the circuit board is also very small in size, providing that installation space is retained in the local coil device for other components, or no additional enlargement is required. When using an acceleration sensor, even taking the circuit board into account, the costs are also significantly lower. In a specific embodiment, for example, in addition to the acceleration sensor, only at least one transistor and a few resistors and capacitors are required on the circuit board.

In one embodiment, the acceleration sensor may be configured for three-dimensional measurement of the inclination (e.g., the acceleration). The sensor data thus consists, for example, of three different components that may be considered projections of the gravitational acceleration (e.g., the g vector), which describes the direction and magnitude of the acceleration due to gravity, on the three sensor axes (e.g., the x-axis, the y-axis, and the z-axis of the sensor coordinate system). With the second portion in an exactly horizontal position, the orientation of the sensor axes may be selected such that the determined sensor data with respect to the x-axis and the z-axis is equal to zero in both cases, while with respect to the y-axis, the g value is measured. If the acceleration sensor is tilted with the second portion about an axis outside the vertical, the orientation with respect to the g vector changes accordingly. The inclination information is thus composed of an inclination of the tiltable portion with respect to the x-axis, the y-axis, and the z-axis. In one embodiment, the acceleration sensor is arranged with respect to the tilt axis of the second portion such that the tilt axis corresponds to one of the sensor axes. For example, the x-axis can correspond to the tilt axis, so that when the second portion of the local coil device is tilted, only the inclination about the x-axis is changed, and the measured value with respect to the x-axis remains unchanged.

In the case of a patient table, for example, on which the local coil device is arranged, the arrangement may be provided such that the axes of the sensor coordinate system and the axes of the table coordinate system may correspond to one another. In this case, the z-axis is the horizontal axis (e.g., the axis in the longitudinal direction of the patient table). The x-axis corresponds to the transverse direction of the patient table, and the y-axis corresponds to the vertical direction of the patient table (e.g., and thus the direction of the g vector). The same orientations of the axes may also apply, for example, to a magnetic resonance device coordinate system in which the patient table is moved. In the ideal case, with the second portion abutting the first portion, the x-axis, y-axis, and z-axis of the sensor coordinate system thus correspond to the corresponding axes of the table coordinate system and the magnetic resonance device coordinate system. Deviations (e.g., in the design), such as tolerances, may be taken into consideration as described in more detail below.

One advantage of an embodiment according to the present embodiments, in which the geometry is converted as a function of the inclination information starting from a basic position (e.g., the position in which the second portion abuts the first portion), is that no predefined coil information or sets of coil information are needed for a specific tilt position, but instead, a single piece of coil information may be used for different tilt angles, since the tilt angle is always calculated anew and enables a determination of the geometry (e.g., the position of the coil elements). In this way, continuous angle ranges (e.g., between 0-45°) may also be covered with just one piece of coil information. At low field strengths, the tilt position or the magnitude of the inclination of the tiltable portion of the local coil device may be purely a matter of comfort (e.g., the angle is adjusted according to the patient's comfort). At high field strengths, the magnitude of the inclination is also relevant to safety, as numerous safety calculations (e.g., SAR) are based on the reclining position of the patient. Therefore, using the local coil device according to the present embodiments, the safety of the patient may also advantageously be further increased.

In a further development of the present embodiments, the local coil device may have a communication device connected to the acceleration sensor. The communication device is configured to transmit the sensor data of the acceleration sensor or data derived therefrom to a control unit, external to the local coil, of a control device of the magnetic resonance device.

The communication device may therefore be configured for data transfer (e.g., for the transfer of sensor data relating to the inclination information or also the inclination information itself) if this is determined locally.

The communication device may have an interface to an I2C bus of the magnetic resonance device and/or may use a coil connector of the local coil device for data transfer.

The transfer may take place galvanically (e.g., via a cable connection when using the coil connector) or via circuit board wiring or data cables when using the I2C bus, or alternatively an SPI bus. The advantage of the I2C bus over the SPI bus is that only two lines are needed for the I2C protocol for the communication protocol sequence, while at least four lines are required for the SPI bus. The I2C bus is also less costly to implement. By contrast, the SPI bus has a higher or faster data transfer rate.

The interface to the I2C bus, or alternatively to the SPI bus, may be arranged on the circuit board. Further, the acceleration sensor and a microcontroller may be arranged on the circuit board. The microcontroller may be a part of a control unit on the local coil side. Accordingly, in an embodiment, sensor data may be captured by the acceleration sensor and transmitted via the communication device to the I2C bus or the SPI bus. An at least partial evaluation of the sensor data may also take place, and this derived data may be transmitted. The respective bus may then forward the sensor data to the control unit external to the local coil. The microcontroller may be configured to evaluate the sensor data in order to determine the inclination information. To this end, the microcontroller may retrieve the data from the acceleration sensor at a sampling rate of 30 Hz, for example. For example, the microcontroller may calculate the scope or magnitude of the inclination and the tilt angle and/or the change in these as the inclination information, as will be explained in more detail below. The sensor data and/or the inclination information and/or an intermediate result may then be transmitted to the control unit external to the local coil. One advantage of using the microcontroller to evaluate the sensor data is that both the payload (e.g., the usable content of the data) and the traffic (e.g., the data traffic as a whole) may be reduced, as only evaluation results previously determined by the microcontroller and thus only relevant data is transmitted to the control unit external to the local coil.

Alternatively, the sensor data may also be transmitted directly via the I2C bus or SPI bus to the control unit external to the local coil, without an evaluating microcontroller being interposed on the local coil side. Accordingly, in this case, the control unit external to the local coil may evaluate the sensor data in order to determine the inclination information and may calculate the tilt angle if appropriate.

Alternatively or in addition to the galvanic transfer of the sensor data, the transfer may also take place via radio, ultrasound, or optically. An additional transfer type has the advantage that if the I2C bus or SPI bus should fail, transfer to the control unit external to the local coil may nonetheless be guaranteed.

In one embodiment, the acceleration sensor may be provided with shielding to prevent or reduce a disruption of the magnetic resonance imaging of the magnetic resonance device.

The shielding may be a hardware shield, for example. For example, a specially designed shielding structure may be used that is configured to minimize the interference it causes to the imaging. Using a shielding may enable the acceleration sensor to be active (e.g., switched on), even during a measurement period of the magnetic resonance device. If an active acceleration sensor is not shielded during imaging by the magnetic resonance device, this may result in the disadvantageous consequence of image artifacts occurring within the magnetic resonance images.

The present embodiments also relate to a magnetic resonance device including at least one local coil device according to the present embodiments and a control device including at least one control unit external to the local coil and at least one control unit on the local coil side. The embodiment of the local coil device with the acceleration sensor makes it possible to obtain inclination information that may be productively used in the control device during operation of the magnetic resonance device. For example, infinitely variable tilting of the second portion relative to the first portion is possible when the inclination information may be processed suitably in the control device.

In a development of the present embodiments, the control device may be configured to evaluate the sensor data of the acceleration sensor to determine the inclination information, which includes a tilt angle of the tiltable second portion of the local coil device with respect to a basic position in which the second portion abuts the first portion.

Owing to the inclination of the second portion relative to the first portion, the position of at least two axes of the sensor coordinate system changes with respect to a fixed coordinate system (e.g., the table coordinate system and/or the magnetic resonance device coordinate system), and thus also the projection of the acceleration due to gravity onto the axes of the sensor coordinate system. If, for example, the second portion is tilted by 5° relative to the first portion (e.g., is inclined about the x-axis), the measured value with respect to the x-axis does not change, but the measured values for both the y-axis and the z-axis change. Accordingly, at a tilt of 5° from the horizontal, the acceleration sensor will determine a measured value for the z-axis that is not equal to zero and a measured value for the y-axis that is not equal to acceleration due to gravity (9.81 m/s²). Owing to the changed projection of the acceleration due to gravity at the y-axis and/or the z-axis, the tilt angle (e.g., in the present example, a tilt angle of 5°) may ultimately be calculated by the control device. In another variant, the change may also be tracked.

As already mentioned, the tilt angle and the inclination information, respectively, may generally be calculated both by the control unit external to the local coil and by the control unit on the local coil side.

As already disclosed, the calculation of the tilt angle may, for example, be based on the assumption that the second portion abuts the first portion in the basic position in the horizontal or assumes a specific base angle relative to the horizontal. In other words, when the local coil device is installed, the first portion may have a defined orientation relative to the vertical. This results, for example, from a specified installation position (e.g., on a patient table). Magnetic resonance devices may be oriented horizontally upon installation. The patient table may also be installed horizontally in the magnetic resonance device. If the local coil arrangement (e.g., in the case of a head coil arrangement) then has a fixed position on or in the patient table, the inclination of the acceleration sensor may thus be converted into a tilt of the second portion of the local coil arrangement (e.g., more specifically, the tilt angle).

According to a development, the control device may be configured to determine the tilt angle under the assumption that a component of the magnetic resonance device (e.g., a patient table), to which the local coil device may be fastened, has a target orientation (e.g., in the horizontal). This assumption need not necessarily apply precisely or sufficiently precisely. Therefore, a deviation in the orientation of the component of the magnetic resonance device with respect to the target orientation may be determined. The determined deviation may be stored in a storage medium.

For example, when operating the magnetic resonance device for the first time, for example, in the context of product safety and quality management, it may first be required that the actual orientation of the magnetic resonance device, or, for example, the patient table, be determined. Owing to structural conditions, for example, it may be the case that the surface or the floor on which the patient table is arranged is not completely level and that the patient table is therefore not parallel to the z-axis (e.g., horizontal). When determining a deviation between the actual orientation of the patient table and the target orientation, the value of the deviation may be stored in a persistent storage medium.

In a development of the present embodiments, the control device may be configured to account for the known deviation when determining the tilt angle.

The tolerances during installation and horizontal leveling of the magnetic resonance device and the patient table or components in general may also result in the inclination particularly about the x-axis having a small deviation. As a result of this, the determined tilt angle may always be slightly changed compared to the absolute angle or the target orientation. Accordingly, the known deviation may be accounted for when determining the tilt angle. To this end, the following calculations may be performed, for example:
Deviation from target orientation=angle of target orientation−angle of actual orientation.
Tilt angle correction=measured tilt angle+deviation from target orientation.

The tilt angle corrected in this way may, as will be explained below, be used to calculate the specific absorption rate (SAR), which is relevant to patient safety. In one embodiment, the calculation of the deviation or the correction of the tilt angle is to be performed only once when operating the magnetic resonance device for the first time in a particular environment. In addition, the calculation of the deviation or the correction of the tilt angle may also be performed at cyclical intervals (e.g., as part of annual maintenance).

According to a development of the present embodiments, the control unit on the local coil side may be configured, if the inclination information indicates a change in the inclination of the second portion, to send an interrupt signal including the tilt angle to the control unit external to the local coil.

In this embodiment variant, the acceleration sensor may thus trigger an interrupt signal at any time, as soon as relevant inclination information has been determined that indicates, for example, a change or a new tilt angle. This has the advantage of lower utilization of the communication and of the control unit external to the local coil, as only one signal is triggered if the sensor data indicates that a new tilt angle is present that is not yet known by the control unit external to the local coil. In this way, it is also possible for the control device to achieve faster reaction times. To realize this variant, the acceleration sensor may be switched on constantly (e.g., also during a complete measurement phase of the magnetic resonance device). In order to prevent possible image artifacts during the imaging process, the acceleration sensor may be shielded with a shielding means, as described above.

Alternatively or in addition to this, the control device may be configured to temporarily activate the acceleration sensor at predefined times during an examination procedure including at least one measurement phase, so that the sensor data from the acceleration sensor may be retrieved by the control device.

In this variant, the acceleration sensor is therefore not permanently active, but rather, the control device may actively retrieve data from the acceleration sensor within cyclically repeating time periods. These time periods may be outside the actual measurement phase of the magnetic resonance device. Accordingly, the acceleration sensor is completely switched off during the measurement phase and may neither calculate nor transmit data during this period, but also cannot have a disruptive effect on the measurement. Alternatively, the entire circuit board on which the acceleration sensor is arranged may also be deactivated so that the I2C or SPI bus interface and the microcontroller, where present, are consequently also deactivated. However, one disadvantage of active retrieval is that the load on the control device is higher than in the previous variant, and also a large volume of data is generated.

The control device may be configured such that the control device may execute both variants. For example, the two variants may be used at different points in time or in the context of specific operating modes.

In one embodiment, at least one part (e.g., at least one portion) of the predefined times may be defined by a specified frequency outside an imaging operation of the magnetic resonance device and/or at least one part (e.g., at least one portion) of the predefined times may be the completion of an installation of the local coil device on a patient table of the magnetic resonance device (e.g., the plugging-in of a coil connector into a socket) and/or the completion of a movement of the patient table into an imaging position.

Generally speaking, the active retrieval may fundamentally take place in two ways, either regularly or, for example, at much less frequent, predefined times. The first of these variants relates to regular retrieval. This may be carried out, for example, with a sampling rate of 1 Hz in the breaks between the measurement phases of the magnetic resonance device. This variant is easy to implement and also functions reliably due to its simplicity. However, one disadvantage of this variant is that for most of the time it produces an unnecessarily large volume of data traffic (e.g., an unnecessarily large data load).

Accordingly, the embodiment variant in which retrieval only takes place at specified times may be provided. This may be after the installation of the local coil device on the patient table and/or after completion of a reclined movement into the imaging position. As a further alternative, an activation of the acceleration sensor may also be provided after completion of every reclined movement (e.g., also after the patient table has traveled out of a patient aperture of the magnetic resonance device and subsequently come to a stop). In one embodiment, there is a delay of 1-2 seconds between the stopping of the patient table and the switching-on of the acceleration sensor or the circuit board. Since the tilt position no longer changes inside the patient aperture (e.g., when the patient table movement is complete and the measurement phase is about to begin), this point in time is particularly reliable and robustly supplies the relevant inclination information (e.g., the relevant tilt angles). Since, in many workflows, the coil connector of the local coil arrangement is only plugged into the corresponding socket once the patient has been positioned, a retrieval at this point in time (e.g., the “coil change event”) may be provided. These two specifically described options also have the advantage that the occurrence of these events is commonly reported in the control device, and thus, no additional new event signals are needed. Another advantage of targeted retrieval is that significantly less data traffic is required.

Generally speaking, neither the patient nor the medical personnel may tilt the tiltable portion of the local coil device during the measurement. A tilting of the tiltable portion may fundamentally only occur outside the patient aperture of the magnetic resonance device. Accordingly, it may be provided for a change in the inclination and thus inclination information to be determined only outside the measurement phases.

In one embodiment, the control device may be configured to determine, from the inclination information, current coil information that describes at least the position of coil elements of the local coil device, and to use the coil information in a reconstruction of a magnetic resonance image from recorded magnetic resonance signals and/or for determining a specific absorption rate for an examination object.

The current coil information may thus be used to determine where in the coordinate system of the magnetic resonance device or the patient table the individual coil elements of the local coil device are arranged. In one embodiment, reference is made to basic coil information that is assigned to the local coil device and describes the geometry of the local coil device (e.g., the coil elements) in a reference inclination (e.g., with the second portion abutting the first portion). If the actual current tilt angle is known from the inclination information, it is readily possible via simple, known geometric relationships to convert the arrangement of the coil elements (e.g., those of the second portion) from the reference inclination to the current tilt angle. As already explained, it is therefore particularly advantageous for the local coil device to keep only basic coil information from which the current coil information may be determined even when the tilt angle is completely freely selectable, after the acceleration sensor provides the necessary inclination information for determining the current coil information to be used.

The specific absorption rate (SAR) is a measure of the absorption of electromagnetic radiation in biological tissue. For example, in magnetic resonance measurements of brain structures or small vessels, measurements may be taken in stronger basic magnetic fields (B0 fields) and/or with coil elements located close to the patient in order to optimize imaging. However, the SAR may increase, especially at high magnetic field strengths, which may lead to unwanted heating of the tissue. To prevent overheating, there are ideal SAR limits that should be adhered to. It is generally advantageous to keep the specific absorption rate (SAR) low. The position of the coil elements may be decisive for the SAR, especially when considered locally, which also takes into account “hotspots.” Therefore, advance calculations or the inclusion of SAR information during the measurement may use the pose of the coil elements of the local coil device. Accordingly, the coil information may be used to calculate the SAR information with sufficient accuracy, as the inclination information describes the correct position and orientation. In this way, compliance with the SAR limit values and patient safety may be provided even in the case of freely selectable tilt angles.

However, in one embodiment, knowledge of the geometrical arrangement of the coil elements of the local coil device (e.g. of the second portion) may be used in the context of image reconstruction or preparation for image reconstruction (e.g., if sensitivity maps of the coil elements that are already known and/or determined are to be used or the like).

Further, if the magnetic resonance device is a positron emission tomography magnetic resonance device that is configured for both magnetic resonance imaging and PET imaging, it is possible for the control device to be configured to use the current coil information to create an attenuation map of the coil elements for the correction of a positron emission tomography signal.

Further, the present embodiments relate to a method for determining an inclination of a second portion that is tiltable relative to a first portion, of a local coil device for a magnetic resonance device. The local coil device includes an acceleration sensor on the second portion and, in an examination procedure in which the local coil device is installed on a component of the magnetic resonance device, inclination information with respect to an inclination and/or a change in the inclination of the tiltable portion of the local coil device being determined from the sensor data of the acceleration sensor.

All statements concerning the local coil device according to the present embodiments and the magnetic resonance device according to the present embodiments may also be applied analogously to the method according to the present embodiments and vice versa, so that the aforementioned advantages may also be achieved with the method.

### BRIEF DESCRIPTION OF THE DRAWINGS

FIG. 1 is a schematic representation of a local coil device according to an embodiment, a tiltable, second portion of the local coil device being tilted relative to a first portion;

FIG. 2 is a schematic representation of the local coil device according to FIG. 1, the local coil device being arranged according to an example embodiment on a patient table of a magnetic resonance device according to an embodiment;

FIG. 3 is a flowchart of a first example embodiment of a method; and

FIG. 4 is a flowchart of a second example embodiment of a method.

### DETAILED DESCRIPTION

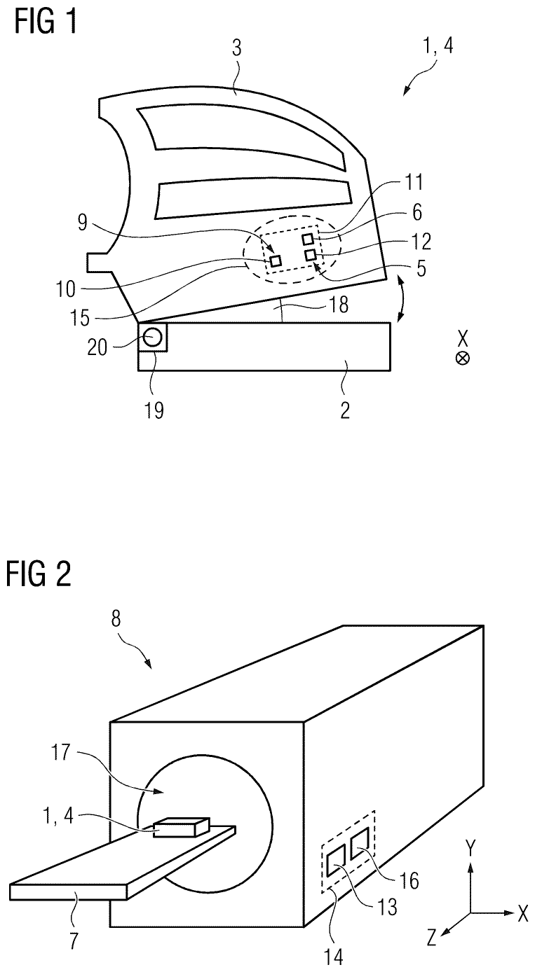

FIG. 1 shows a local coil device 1 according to an embodiment including a first, non-tiltable portion 2 and a second portion 3 that is tiltable relative to the first portion 2. The local coil device 1 is configured as a head coil 4. The coil elements of the local coil device 1, which are not shown in any further detail, are all arranged in the tiltable second portion 3. The local coil device 1 further includes a control unit 5 on a local coil side and an acceleration sensor 6 using which sensor data relating to an inclination of the tiltable second portion 3 relative to the first portion 2 is determined. In one operating state, the local coil device 1 is arranged on a patient table 7 as a component of a magnetic resonance device 8 according to the present embodiments (cf., FIG. 2).

The second portion 3 may be brought into any tilt positions in a tilt range (e.g., from 0 to 45°) and may be locked therein by a detent 19, which is only indicated here.

The acceleration sensor 6 is configured for three-dimensional measurement of the acceleration. Accordingly, the acceleration sensor 6 may be used to measure the acceleration relative to the acceleration due to gravity, from which an inclination of the acceleration sensor 6 relative to the vertical direction (e.g., the y-axis of a table coordinate system and/or magnetic resonance device coordinate system) is determined. As shown in FIG. 2, in the patient table coordinate system, the x-axis describes an axis in the transverse direction of the patient table, the y-axis describes a vertical axis in the vertical direction of the patient table, and the z-axis describes a horizontal axis in the longitudinal direction of the patient table. In the present example embodiment, the tiltable second portion 3 of the local coil device 1 may be inclined by way of example about the, for example, coinciding or parallel x-axis in the patient table coordinate system and in the sensor coordinate system as tilt axis 20, or about a tilt axis 20 parallel to the x-axis.

Further, the local coil device 1 has a communication device 9. The communication device 9 has an interface 10 to an I2C bus that provides a communication connection via the coil connector to a control unit 13 external to the local coil (cf., FIG. 2). Both the acceleration sensor 6 and the I2C bus interface 10 are arranged on a circuit board 11. Arranged next to these on the circuit board 11 is a microcontroller 12 that is part of or forms the control unit 5 on the local coil side. The microcontroller 12 retrieves sensor data from the acceleration sensor 6 (e.g., at a frequency of 30 Hz). The microcontroller 12 is configured to evaluate the sensor data to determine inclination information (e.g., with respect to a change in the inclination and/or a tilt angle 18). In other example embodiments, merely a partial evaluation or a simple forwarding of the sensor data may also take place. The sensor data and/or the data derived therefrom (e.g., at least the inclination information) is then forwarded by the microcontroller 12 via the I2C bus to the control unit 13 external to the local coil (cf. FIG. 2). If the tilt angle 18 is not already determined as inclination information, the control unit 13 external to the local coil may then be configured to use the transmitted sensor data to determine the tilt angle 18 (e.g., as the angle between the first portion 2 and the second portion 3 starting from a basic position in which the second portion 3 abuts the first portion 2) of the local coil device 1.

In the present example embodiment, the transfer of the sensor data and/or the data derived therefrom takes place galvanically (e.g., via the I2C bus). Alternatively, the data transfer may also take place optically, via radio, or via ultrasound.

FIG. 2 shows the magnetic resonance device 8 according to the present embodiments, including the patient table 7, the local coil device 1 arranged on the patient table 7, and a patient aperture 17. Further, the magnetic resonance device 8 has a control device 14 that is formed by the control unit 5 on the local coil side and the control unit 13 external to the local coil.

Optionally, the acceleration sensor 6 of the local coil device 1 is shielded by shielding 15 (cf., FIG. 1), which is a hardware shield (not shown in FIG. 2). Owing to the shielding 15, the acceleration sensor 6 may also be switched on during a measurement phase of the magnetic resonance device 8.

In a first embodiment variant, the acceleration sensor 6 may be switched on for a longer period, and, if appropriate, also during the measurement phase if the shielding 15 is provided. For the first measurement after switching on and whenever a change in the sensor data or the inclination information is detected, the microcontroller 12 sends an interrupt signal to the control unit 13 external to the local coil (e.g., via the I2C bus). The interrupt signal includes the tilt angle 18 or the inclination information in general. Outside these cases, transmission is then not necessary and is also not carried out.

In a second variant, the acceleration sensor 6 of the local coil device 1 is switched off during the measurement phase of the magnetic resonance device 8. Accordingly, the acceleration sensor 6 need not be shielded with a hardware shield 15. The complete circuit board 11 may also be switched off. The control unit 13 external to the local coil may automatically switch on the acceleration sensor 6 or the circuit board 11 so that the acceleration sensor 6 may measure the inclination and provide the measurement results. The acceleration sensor is thus queried in a targeted manner at specific, predefined times (e.g., after the table has stopped inside the patient aperture 17 in an imaging position or after a coil connector has been plugged in on the patient table 7). After the acceleration sensor 6 or the circuit board 11 has been switched on, the microcontroller 12 performs a retrieval as described above.

The control device 14 is configured to evaluate the sensor data relating to the inclination information that is determined by the acceleration sensor 6 (e.g., to calculate the tilt angle 18). The tilt angle 18 is calculated under the assumption that the patient table 7 on which the local coil device 1 is arranged is horizontal. The basic position in which the second portion 3 abuts the first portion 2 would then also be a horizontal orientation of the second portion 3, whereby the local coil device 1 is indeed positioned on the patient table 7. The horizontal orientation of the patient table 7 is further dictated by the horizontal orientation of the magnetic resonance device 8 as a whole. However, there may also be deviations within the scope of tolerances.

In order to determine the actual orientation of the patient table 7 (and thereby of the second portion 3 and thus of the sensor coordinate system in the basic position), the deviation of the patient table 7 from the horizontal target orientation is determined (e.g., in the context of maintenance). It is therefore determined whether the patient table 7, as described above, is parallel to the z-axis and therefore horizontal. In the event of any deviation, such as may occur, for example, due to structural conditions, such as unevenness in the floor or general tolerances during installation, this deviation is stored in a storage medium 16 that is, for example, a persistent storage medium. For every new calculation of the tilt angle 18, the deviation in the orientation of the patient table 7 may be incorporated so that the tilt angle 18 is corrected by the deviation in the orientation of the patient table 7 from the target orientation.

Further, the control device 14 uses the inclination information (e.g., the tilt angle 18) to determine current coil information from basic coil information for the local coil device 1. The basic coil information describes the geometrical arrangement of the coil elements of the local coil device 1 in the basic position in which the second portion 3 abuts the first portion 2. On this basis, if a tilt angle 18 indicates a different inclination, an updated geometry may easily be determined. The current coil information is used, for example, to determine or calculate the specific absorption rate, and, if appropriate, also for reconstruction of a magnetic resonance image.

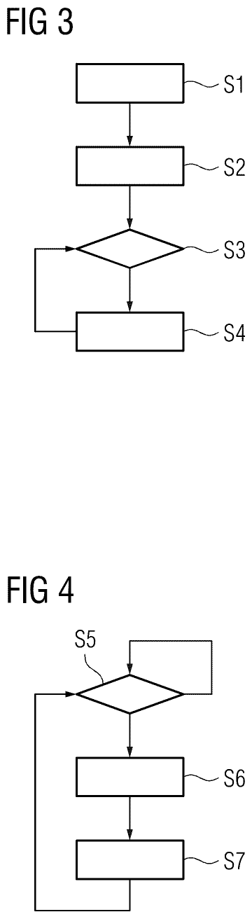

FIG. 3 shows a flowchart of a first embodiment variant of the method according to the present embodiments, including the determination of the inclination of the second portion 3, which is tiltable relative to the first portion 2, of the local coil device 1. Here it is assumed that the local coil device 1 and a patient are first positioned on the patient table 7 for an examination procedure. Once the local coil device 1 is connected, in this first embodiment variant in which a shielding 15 is provided, in act S1, the measuring arrangement on the circuit board 1 is also activated (e.g., the acceleration sensor 8, the microcontroller 12, and the I2C bus interface 10). In act S2, after this activation and the first determination of the tilt angle 18 as inclination information, a first transmission of the inclination information to the control unit 13 external to the local coil as interrupt signal also takes place.

From then, in act S3, with ongoing operation of the acceleration sensor 6 (e.g., cyclical recording of sensor data), monitoring is carried out to determine whether a change in the inclination information (e.g., the tilt angle 18) is indicated. Only in this case is the (updated) inclination information sent again in act S4 to the control unit 13 external to the local coil, which thus learns of the change and its content. This is continued until the local coil device 1 is removed again from the patient table 7, and the coil connector is also unplugged so that the circuit board 11 is once again de-energized.

In one embodiment, the activation may occur not automatically upon connection, but rather may be permanently present or controlled by the control unit 13 external to the local coil.

This first variant may be understood as an “interrupt” variant, as data traffic only takes place and is only necessary when a change occurs.

FIG. 4 explains a further embodiment variant that may be understood as a “retrieval” variant. Here, the acceleration sensor 6 or the measuring arrangement on the circuit board 11 is not permanently active, but instead is activated in a targeted manner by the control unit 13 external to the local coil at predefined times and thus has its data retrieved.

Therefore, in act S5, the control unit 13 external to the local coil monitors whether one of the predefined times in the examination procedure is present. In this case, these are the connection of the local coil device 1 (e.g., plugging-in of the coil connector, “coil change event”), and the completion of a movement of the patient table 7 into an imaging position in the patient aperture 17. This takes advantage of the fact that both events are already reported by event signals in the control device 14 and that, after entering the patient aperture 17 or during the measurement phase in which imaging takes place, no more changes to the tilt angle should occur.

When a predefined time is reached, the acceleration sensor 6 is activated in act S6. In act S7, the acceleration sensor 6 records sensor data, the microcontroller 12 determines the inclination information (e.g. the tilt angle 18), and the inclination information is sent as a response signal via the I2C interface 10 and the I2C bus to the control unit 13 external to the local coil.

In all cases, the correction described with respect to the imperfect horizontal orientation in the basic position may be applied; after this, the corresponding correction value is available in the storage medium 16.

To determine this value, when using the magnetic resonance device 8 for the first time, an evaluation of the orientation of the magnetic resonance device 8 or the patient table 7 may be performed in the context of product safety and quality management. Here, for example, the local coil device 1 may be arranged on the installed patient table 7 and measured in the basic position (e.g., second portion 3 abuts the first portion 2) to determine whether a horizontal orientation is actually present. However, other data sources may also be used in order to determine a deviation in the actual orientation of the patient table 7 from the, for example, horizontal target orientation. If this deviation exceeds a threshold value, the deviation may be stored in the storage medium 16.

In both embodiment variants, the control unit 13 external to the local coil uses the inclination information to determine, from basic coil information that describes the arrangement of the coil elements in the basic position, current coil information that describes the geometrical arrangement and thus also the course of the coil elements at the current tilt angle 18. This current coil information is used, for example, for advance calculation of the global and local SAR or to keep values for this purpose in order to prevent a violation of SAR limit values. Optionally, the current coil information may also be used for or taken into consideration during image reconstruction.

Independent of the grammatical term usage, individuals with male, female, or other gender identities are included within the term.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A local coil device for a magnetic resonance device, the local coil device comprising:
a first portion and a second portion, the second portion being tiltable relative to the first portion; and
an acceleration sensor on the second portion, the acceleration sensor being configured to generate sensor data, the sensor data being usable to determine inclination information with respect to an inclination, a change in the inclination, or the inclination and the change in the inclination of the tiltable second portion of the local coil device.

2. The local coil device of claim 1, further comprising a communication device connected to the acceleration sensor,
wherein the communication device is configured to transmit the sensor data of the acceleration sensor or data derived from the sensor data to a control unit, external to the local coil, of a control device of the magnetic resonance device.

3. The local coil device of claim 2, wherein the communication device has an interface to an I2C bus of the magnetic resonance device, uses a coil connector of the local coil device for data transfer, or a combination thereof.

4. The local coil device of claim 1, wherein the acceleration sensor comprises shielding configured to prevent or reduce a disruption of magnetic resonance imaging of the magnetic resonance device.

5. A magnetic resonance device comprising:
at least one local coil device, a local coil device of the at least one local coil device comprising:
a first portion and a second portion, the second portion being tiltable relative to the first portion; and
an acceleration sensor on the second portion, the acceleration sensor being configured to generate sensor data, the sensor data being usable to determine inclination information with respect to an inclination, a change in the inclination, or the inclination and the change in the inclination of the tiltable second portion of the local coil device
and
a control device comprising:
at least one control unit external to the local coil device; and
at least one control unit on a local coil device side.

6. The magnetic resonance device of claim 5, wherein the control device is configured to evaluate the sensor data of the acceleration sensor to determine the inclination information, and
wherein the inclination information comprises a tilt angle of the tiltable second portion of the local coil device with respect to a basic position in which the second portion abuts the first portion.

7. The magnetic resonance device of claim 6, wherein the control device is configured to determine the tilt angle under an assumption that a component of the magnetic resonance device, to which the local coil device is fastenable, has a target orientation,
wherein a deviation in the orientation of the component of the magnetic resonance device with respect to the target orientation is determinable, and
wherein the determined deviation is storable in a storage medium.

8. The magnetic resonance device of claim 7, wherein the component of the magnetic resonance device is a patient table, and
wherein the target orientation is in the horizontal.

9. The magnetic resonance device of claim 7, wherein the control device is configured to account for the known deviation when determining the tilt angle.

10. The magnetic resonance device of claim 6, wherein the control unit on the local coil side is configured, when the inclination information indicates a change in the inclination of the second portion, to send an interrupt signal comprising the tilt angle to the control unit external to the local coil.

11. The magnetic resonance device of claim 5, wherein the control device is configured to temporarily activate the acceleration sensor at predefined times during an examination procedure comprising at least one measurement phase, so that the sensor data from the acceleration sensor is retrievable by the control device.

12. The magnetic resonance device of claim 10, wherein at least one portion of the predefined times is defined by a specified frequency outside an imaging operation of the magnetic resonance device, at least one portion of the predefined times is completion of an installation of the local coil device on a patient table of the magnetic resonance device, completion of a movement of the patient table into an imaging position, or the completion of the installation and the completion of the movement, or a combination thereof.

13. The magnetic resonance device of claim 12, wherein at least one portion of the predefined times is the plugging-in of a coil connector into a socket.

14. The magnetic resonance device of claim 5, wherein:
the control device is configured to determine, from the inclination information, current coil information that describes at least a position of coil elements of the local coil device, and use the current coil information in a reconstruction of a magnetic resonance image from recorded magnetic resonance signals, for determining a specific absorption rate for an examination object, or in the reconstruction and for determining the specific absorption rate;
when the magnetic resonance device is a positron emission tomography magnetic resonance device, the control device is configured to use the current coil information to create an attenuation map of the coil elements for correction of a positron emission tomography signal; or
a combination thereof.

15. A method for determining an inclination of a second portion of a local coil device that is tiltable relative to a first portion of the local coil device for a magnetic resonance device, wherein the local coil device comprises an acceleration sensor on the second portion, the method comprising:
in an examination procedure in which the local coil device is installed on a component of the magnetic resonance device, determining inclination information with respect to an inclination, a change in the inclination, or the inclination and the change in the inclination of the tiltable second portion of the local coil device from the sensor data of the acceleration sensor.
